(19) United States
(12) Patent Application Publication
(10) Pub. No.: US 2017/0184738 A1
(43) Pub. Date: Jun. 29, 2017

(54) DEVICE AND METHOD SIMULATING THE DETECTION OF MOVING RADIOACTIVE SOURCES

(71) Applicant: COMMISSARIAT A L'ENERGIE ATOMIQUE ET AUX ENERGIES ALTERNATIVES, Paris (FR)

(72) Inventors: Mathieu THEVENIN, Saclay (FR); Karim BOUDERGUI, Nogent-Le-Phaye (FR)

(73) Assignee: COMMISSARIAT A L'ENERGIE ATOMIQUE ET AUX ENERGIES ALTERNATIVES, Paris (FR)

(21) Appl. No.: 15/302,122

(22) PCT Filed: Apr. 21, 2015
(86) PCT No.: PCT/EP2015/058558

§ 371 Date: Oct. 5, 2016

(30) Foreign Application Priority Data
Apr. 23, 2014 (FR) 14 53645

(51) Int. Cl. G01T 7/00; G01R 29/08; G06F 17/50; G01B 7/14

(52) U.S. Cl. CPC G01T 7/005; G01B 7/14; G01R 29/0871; G06F 17/5009

(57) ABSTRACT

A device simulating detection of at least one moving radioactive source, including a receiver receiving signals transmitted by at least one signal transmitter, the device including a pulse generator coupled to the receiver and configured to determine a distance between the receiver and the at least one transmitter from a signal received from the at least one transmitter by the receiver, to generate pulses of which the number varies depending on the distance detected, and to deliver the generated pulses to an electronic processing unit to be tested, configured to be coupled, in nominal detection usage, to one or more detectors of one or more radioactive sources.

### TECHNICAL FIELD

The field of the invention is that of nuclear instrumentation, and more particularly that of the testing, the calibration and the maintenance of radioactive source detection devices. In this context, the invention targets a system simulating the detection of moving radioactive sources, notably for the purposes of testing nuclear instrumentations.

### STATE OF THE PRIOR ART

The testing of nuclear instrumentations under real or realistic conditions necessitates resorting to radioactive sources. Although this may sometimes be envisaged in the laboratory, the use of certain radioactive elements is prohibited and regulated (polonium, mercury, etc.), or hazardous (plutonium). And even though laboratory tests can be carried out, this is not the case of tests in open or public environments (ports, airports, etc.) all the same necessary in order to validate developments or to test the operation of certain instruments, such as walk-through detection units or spectrometers for example.

In order to get around this difficulty in the field of the training of radiation protection personnel, existing solutions to date propose using a moving radio transmitter device with which is associated a radio receiver, or instead resorting to a moving ultrasonic transmitter and an associated sensor, which makes it possible to easily vary the distance and to illustrate the effect of shielding. These devices, used for training, are nevertheless only able to indicate an equivalent radiation level estimated without taking into account the nature of the radio transmitter. Moreover, they cannot be connected to any system for measuring or processing the signal, such as a spectrometer for example, and thus cannot make it possible to test a complete radioactive source detection system.

Other approaches make it possible to get away from this latter problem by connecting onto a complete system a signals generator in place of the detectors. Such a generator may notably make it possible to simulate a large variety of radioactive sources. Nevertheless, these approaches do not make it possible to simulate a distant source, and notably a moving source, since they require the connection of the signals generator in place of the detector and generate a signal of which the characteristics have been programmed.

Moreover, these solutions are limited to a single detector and cannot be used to test systems having a large number of detectors.

### DESCRIPTION OF THE INVENTION

The objective of the invention is to make it possible to carry out exterior tests, outside of the laboratory, of nuclear instrumentations, while avoiding the use of a radioactive source, whatever the instrument to be tested, including spectrometers. More particularly, it aims to integrate in a complete radioactive source detection system a system making it possible to simulate a moving radioactive source, which is today inexistent.

To this end, the invention proposes a device simulating the detection of at least one moving radioactive source, including a receiver of signals transmitted by at least one signals transmitter, characterised in that it comprises a pulse generator coupled to the receiver and configured to determine a distance between the receiver and the at least one transmitter from a signal received from the at least one transmitter by the receiver, to generate pulses of which the number varies as a function of the distance detected, and to deliver the generated pulses to an electronic processing unit to be tested, intended to be coupled, in nominal detection usage, to one or more detectors of one or more radioactive sources.

Certain preferred but non-limiting aspects of this device are the following:
the pulse generator is configured to periodically determine a number of pulses to generate as a function of the determined distance, and to generate randomly said number of determined pulses during the period following said determination;
the pulse generator is further configured to generate pulses of which the shape is characteristic of one or more radioactive sources, the shape of the pulses to generate being able to include an amplitude, a rise time and a fall time of the pulses;
the amplitude of the pulses is determined by the pulse generator from an energy spectrum representing a probability of appearance of pulses as a function of the amplitude;
the pulse generator is configured to extract the energy spectrum from the signal received from the transmitter by the receiver;
the pulse generator is configured to modify the energy spectrum as a function of characteristics of a detector to simulate.

The invention also relates to a system simulating the detection of at least one moving radioactive source, including a device as described previously, and an electronic processing unit to be tested, intended to be coupled, in nominal detection usage, to one or more detectors of one or more radioactive sources, the pulse generator being coupled, on the one hand, to the receiver and, on the other hand, to the electronic processing unit.

### BRIEF DESCRIPTION OF THE DRAWINGS

Other aspects, aims, advantages and characteristics of the invention will become clearer on reading the following detailed description of preferred forms of embodiment thereof, given by way of non-limiting example, and made with reference to the appended drawings in which:

FIG. 1 is a diagram representing a possible embodiment of the device according to the invention;

FIG. 2 represents the random generation over time of a number of pulses as a function of the detected distance separating the receiver;

FIGS. 3 and 4 illustrate two possible embodiment variants of the pulse generator of the device according to the invention;

FIG. 5 represents an energy spectrum of a radioactive source in the form of probability of appearance of pulses as a function of their amplitude.

### DETAILED DESCRIPTION OF PARTICULAR EMBODIMENTS

The invention relates to a device simulating the detection of at least one moving radioactive source, this device making it possible to test an electronic processing unit T which is coupled, in nominal detection usage, to one or more detectors of one or more radioactive sources.

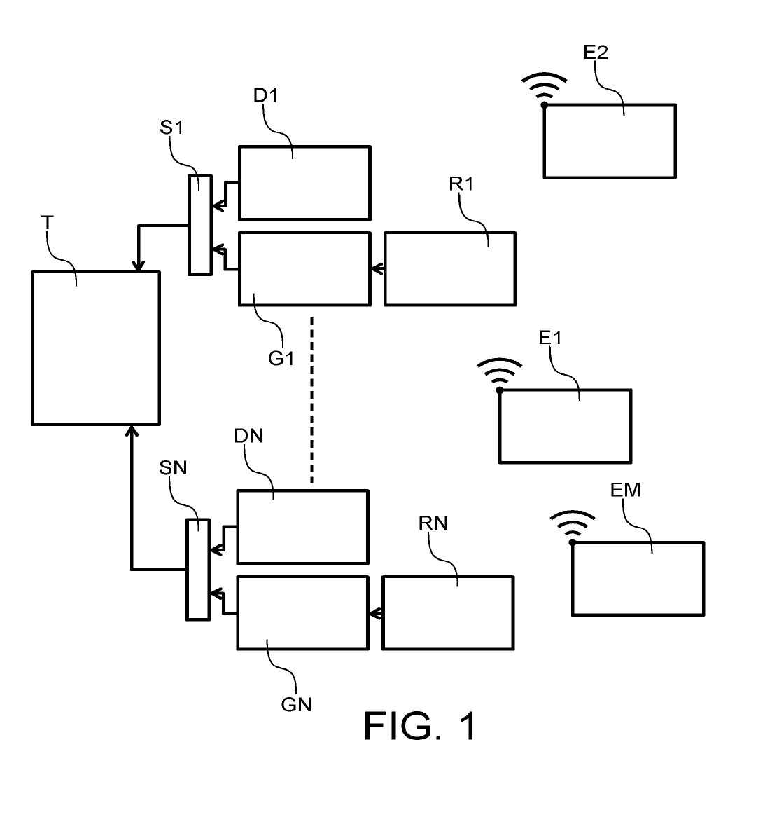

With reference to FIG. 1, the device includes at least one receiver R1, RN of signals transmitted by at least one signal transmitter E1, E2, EM, each of the transmitters being localised and potentially moved to simulate one or more radioactive sources, notably moving sources.

The signals are preferably wireless signals, for example RF (Wifi, Bluetooth®, etc.), ultrasonic or light signals. A wired technology may nevertheless be exploited, to the detriment certainly of the flexibility of the device which is the subject matter of the invention.

The device moreover comprises at least one pulse generator G1, GN coupled, on the one hand, to a receiver R1, RN, and intended to be coupled, on the other hand, to the electronic processing unit T to be tested.

A pulse generator G1, GN is more precisely configured to determine a distance between the receiver R1, RN to which it is coupled and one of the signal transmitters E1, E2, EM from a signal received from the transmitter by the receiver. The pulse generator G1, GN thus determines a distance to each of the transmitters E1, E2, EM when several transmitters are provided.

A pulse generator G1, GN is moreover configured to generate pulses of which the number varies as a function of the detected distance(s).

The signal generated by a pulse generator G1, GN has the same electrical characteristics as the signal generated by a detector D1, DN of one or more radioactive sources. In a possible embodiment, the pulse generator(s) G1, GN are configurable so as to generate signals corresponding to different types of detector (scintillator, semiconductor, etc.).

In a possible embodiment, the device includes at least one selection module S1, SN configured to make it possible to couple selectively the electronic processing unit T to a detector D1, DN of one or more radioactive sources in nominal detection usage, or to a pulse generator G1, GN in test phase of the electronic processing unit.

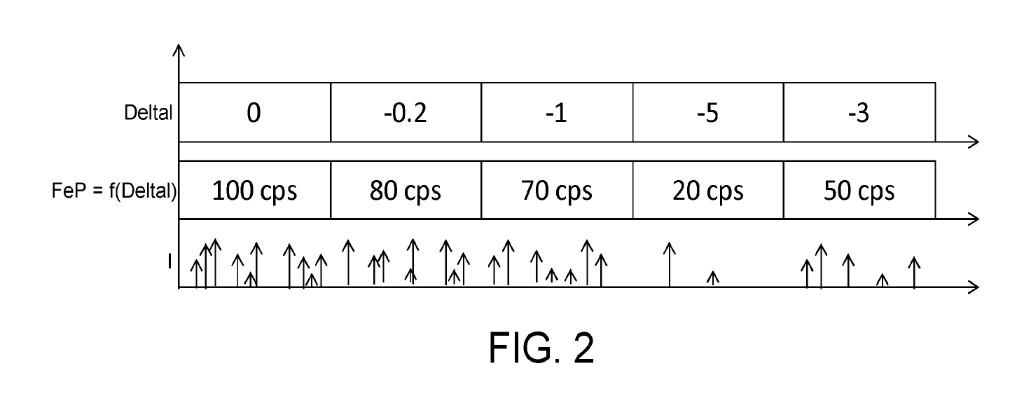

With reference to FIG. 2, the pulse generator may be configured to periodically determine a number of pulses to generate as a function of the determined distance(s) Deltal, and to generate randomly said number of determined pulses during the period following said determination.

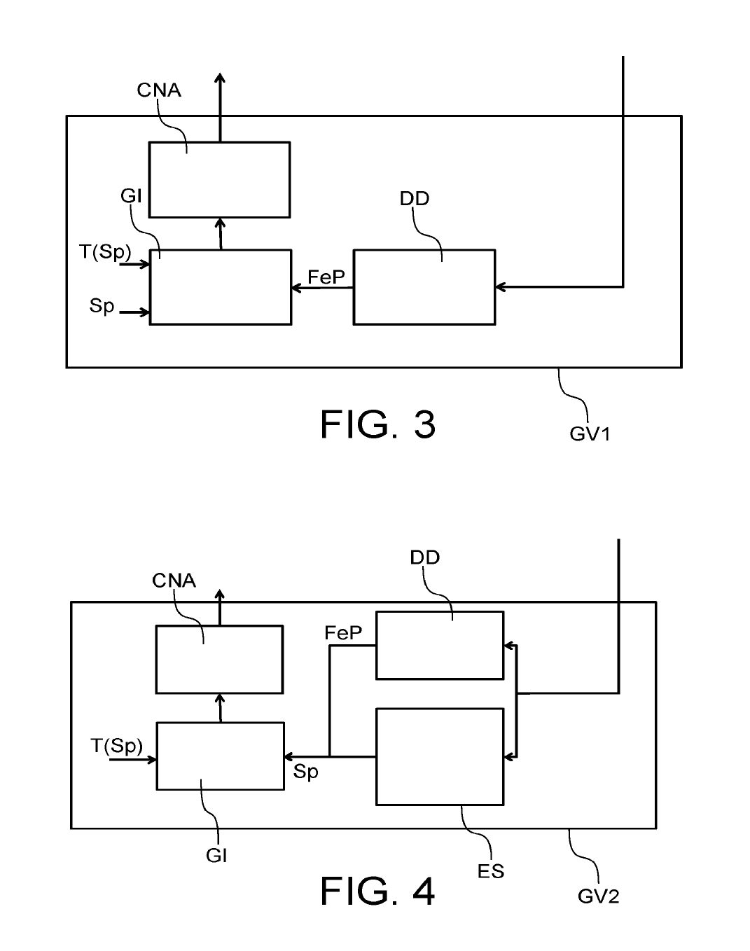

With reference to FIGS. 3 and 4 illustrating two variants of embodiment of the pulse generator GV1, GV2, the latter comprises a module DD configured to determine the distance separating the receiver to which it is coupled from a transmitter, for example from a measurement of the amplitude of the signal received by the receiver, and to determine the number of pulses to generate.

Generally speaking, if the radioactive source simulated by a transmitter moves away, the transmitting frequency of the pulses FeP decreases. Similarly, if the simulated radioactive source comes closer, then the transmitting frequency FeP increases. The transmission frequency may notably reduce according to the square of the distance.

The determination of the distance is carried out regularly, such that the transmission frequency FeP is updated regularly as illustrated by FIG. 3. In order to simulate physical reality, a favoured embodiment makes the pulses generate at random instants, for example following a Poisson law, during the period of validity of the determined distance in order that the generation frequency tends towards FeP.

Obviously, in the presence of several transmitters, several distances are determined, a number of pulses to generate is determined, notably from each of the determined distances, and the pulse generator generates a total number of pulses corresponding to the sum of the numbers of pulses each determined from a distance to a transmitter.

The determination of the distance separating a receiver from a transmitter may be based on the measurement of the attenuation of the signal transmitted by a transmitter and received by a receiver in order to determine the change in the relative distance between the transmitter and the receiver. A calibration (which may be done in the laboratory) makes it possible to go from relative to absolute distance. In FIG. 2, the reference 100 corresponds to the reference of the first measurement, and Deltal corresponds to the change in the relative distance compared to the first measurement, knowing that the intensity of the signal changes with the square of the speed.

A localisation device, such as a GPS, placed at the level of a transmitter, and optionally at the level of a receiver, makes it possible to refine the distance measurement.

The measurement of the amplitude of the signal transmitted can also vary as a function of the environment (and not only the distance) and notably due to the screen effect (a concrete wall induces a considerable reduction in the amplitude of the signal transmitted without all the same being caused by a large distance). This phenomenon, which is the same as for ionising radiation, is advantageously taken into account by the invention which makes it possible to vary the count rate as a function of the presence or not of such a screen effect in the same way as for the distance. In an implementation, a localisation device may advantageously be exploited to refine the generation of pulses. In fact, if an attenuated signal is received even though the distance is near, it is possible to deduce therefrom the presence of a screen. Yet, a screen acts as a band-pass filter (generally high-pass) on the spectrum of the signal. It is thus possible to use automatically such a filter when a screen is detected in order to generate a “degraded” spectrum desired by the presence of a screen, and does so from the initially desired spectrum. This makes it possible to increase the realism of the simulation. Finally the nature of the screen may be taken into account in order to select the band-pass filter ad hoc. This is possible by techniques of modelling of the environment, of increased reality, etc.

A pulse generator is moreover configured to generate pulses of which the shape and the intensity are characteristics of the radioactive source(s) simulated.

The shape of the pulses to generate includes typically the following characteristics: an amplitude, a rise time and a fall time, a fall shape (typically more or less convex). This shape is given by the characteristics of the detector to simulate, and may be influenced by the potential presence of a screen on the transmitter-receiver path. These characteristics are supplied to the pulse generator, and are preferably configurable.

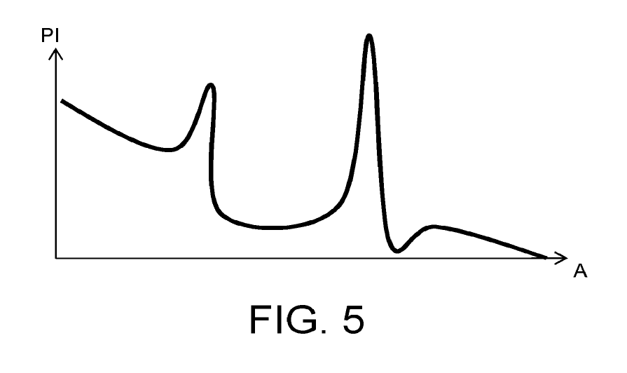

The intensity of the pulses may be determined by the pulse generator from a predefined energy spectrum Sp, corresponding to one or more radioactive elements and representing for example a probability of appearance of the pulses PI as a function of the amplitude A as represented in the example of FIG. 5.

The pulse generator may be configured to modify the energy spectrum as a function of characteristics of a detector to simulate. A transformation T(Sp) may thus be applied to the spectrum Sp, this transformation corresponding to the transfer function of the simulated detector.

The energy spectrum Sp may be supplied directly to a module for transmitting pulses GI from the pulse generator GV1, as represented in FIG. 3. This spectrum Sp may be chosen by the user, for example by being selected in a database.

In a variant represented in FIG. 4, the pulse generator GV2 includes an extraction module ES configured to extract the energy spectrum Sp from the signal received from the transmitter by the receiver. The signal transmitted by the transmitter is for example modulated to carry this information.

The transmitter may moreover transmit the characteristics of each pulse to generate, associated or not with the identification of one or more pulse generators in order that the latter can know what pulses to generate. In such a case, the pulse generator randomly selects the pulses to generate among those sent by the transmitter while respecting the criterion of the number of pulses to generate as a function of the detected distance.

As represented in FIGS. 3 and 4, the pulse generator GV1, GV2 may moreover comprise a digital-analogue conversion module CNA, arranged at the output of the pulse transmission module GI and making it possible to supply the electronic processing unit T with analogue pulses.

Each pulse generator may moreover be configurable. The configuration elements include for example the spectrum of the radioactive element(s) to simulate, the count rate to simulate, or instead the type of detector to simulate which has an impact on the shape of the generated pulses. The configuration elements may notably be communicated via signals transmitted by the transmitter.

It will be understood that the invention proposes a moving device making it possible to simulate one or more fixed or moving radioactive sources and to detect them. One or more transmitters, for example radiofrequency, make it possible to simulate the source or the sources. One or more receivers make it possible to receive the signal(s) from the transmitter(s) and to deduce therefrom one or more distances, for example as a function of the intensity of the RF signals, corresponding to the detection of the simulated source(s). A signal responding to the characteristics of one or more radionuclides is then generated as a function of the characteristics of the signal transmitted by the transmitter by a pulse generator that replaces the detectors normally used (fission chamber, plastic scintillators, Nal etc.) within the scope of nuclear instrumentation applications.

The invention is not limited to the device as described previously, but also extends to a complete system incorporating the transmitter(s), and if need be the electronic processing unit to be tested.

The invention moreover further extends to a simulation method for detecting at least one moving radioactive source with the aid of the device described previously, and notably to a method including the transmission and the reception of signals by a transmitter and a receiver of signals, respectively, characterised in that it comprises the steps implemented by a pulse generator coupled both to the receiver and to an electronic processing unit to be tested, intended to be coupled, in nominal detection usage, to one or more detectors of one or more radioactive sources, consisting in:
determining a distance between the receiver and the transmitter from a signal received from the transmitter by the receiver; and
generating pulses of which the number varies as a function of the detected distance.

Finally, the invention also extends to a computer programme product, including code instructions for the execution of the steps of this method implemented by the pulse generator, when said programme is executed on a computer.

1-13. (canceled).

14. A device simulating detection of at least one moving radioactive source, comprising:
a receiver to receive signals transmitted by at least one signal transmitter; and
a pulse generator coupled to the receiver and configured to determine a distance between the receiver and the at least one transmitter from a signal received from the at least one transmitter by the receiver, to generate pulses of which the number varies as a function of the determined distance, and to deliver the generated pulses to an electronic processing unit to be tested,
the electronic processing unit configured to be coupled, in nominal detection usage, to one or more detectors of one or more radioactive sources.

15. The device according to claim 14, wherein the pulse generator is configured to periodically determine a number of pulses to generate as a function of the determined distance, and to generate randomly the number of determined pulses during a period following the determination.

16. The device according to claim 14, wherein the pulse generator is further configured to generate pulses of which the shape is characteristic of one or more radioactive sources.

17. The device according to claim 16, wherein the shape of the pulses includes an amplitude, a rise time, and a fall time of the pulses.

18. The device according to claim 17, wherein the amplitude of the pulses is determined by the pulse generator from an energy spectrum representing a probability of appearance of pulses as a function of the amplitude.

19. The device according to claim 18, wherein the pulse generator is configured to extract the energy spectrum from the signal received from the transmitter by the receiver.

20. The device according to claim 19, wherein the pulse generator is configured to modify the energy spectrum as a function of characteristics of a detector to simulate.

21. The device according to claim 14, comprising a plurality of pulse generators, each coupled to a receiver of the signals transmitted by the at least one transmitter.

22. A system simulating detection of at least one moving radioactive source, comprising:
a device according to claim 14; and
an electronic processing unit to be tested, the electronic processing unit configured to be coupled, in nominal detection usage, to one or more detectors of one or more radioactive sources, the pulse generator coupled to the receiver and to the electronic processing unit.

23. The system according to claim 22, further comprising a selection module configured to make it possible to couple selectively the electronic processing unit to a detector of one or more radioactive sources in nominal detection usage, or to the pulse generator in a test phase of the electronic processing unit.

24. The system according to claim 23, further comprising one or more moving signal transmitters.

25. A simulation method of detecting at least one moving radioactive source, comprising:
transmitting signals by at least one transmitter;
receiving of signals by a receiver; and
implemented by a pulse generator, coupled to the receiver and to an electronic processing unit to be tested, the electronic processing unit being configured to be coupled, in nominal detection usage, to one or more detectors of one or more radioactive sources:
determining a distance between the receiver and the at least one transmitter from a signal received from the at least one transmitter by the receiver, and
generating pulses of which the number varies as a function of the determined distance.

26. A non-transitory computer readable medium, including computer code instructions for execution of the method according to claim 25 implemented by the pulse generator, when the computer code instructions are executed on a computer.
